(19) United States
(12) Patent Application Publication
(10) Pub. No.: US 2005/0251777 A1
(43) Pub. Date: Nov. 10, 2005

(54) Method and structure for implementing enhanced electronic packaging and PCB layout with diagonal vias

(75) Inventors: Gerald Keith Bartley, Rochester, MN (US); Darryl John Becker, Rochester, MN (US); Paul Eric Dahlen, Rochester, MN (US); Philip Raymond Germann, Oronoco, MN (US); Andrew B. Maki, Rochester, MN (US); Mark Owen Maxson, Mantorville, MN (US)

Correspondence Address: IBM CORPORATION;ROCHESTER IP LAW DEPT. 917, 3605 HIGHWAY 52 NORTH, ROCHESTER, MN, 55901-7829, US

(73) Assignee: International Business Machines Corporation, Armonk, NY (US)

(21) Appl. No.: 10/839,488

(22) Filed: May 5, 2004

(51) Int. Cl. G06F 17/50; H01L 21/44

(52) U.S. Cl. 716/15; 438/106

(57) ABSTRACT

A method and structure are provided for implementing enhanced electronic packaging and printed circuit board (PCB) layout. A diagonal via is formed at a selected angle between a first side and an opposite second side of a printed circuit board at a selected printed circuit board location. The diagonal via is plated with an electrically conductive material. Diagonal vias are used to interconnect between a high-density pitch on the first side and a larger pitch on the opposite second side of the printed circuit board. The diagonal vias can be used to selectively interconnect electrical patterns of selected layers and eliminate the use of blind and buried vias.

### FIELD OF THE INVENTION

The present invention relates generally to the data processing field, and more particularly, relates to a method and structure for implementing enhanced electronic packaging and printed circuit board (PCB) layout with diagonal vias.

### DESCRIPTION OF THE RELATED ART

As used in the present specification and claims, the term printed circuit board or PCB means a substrate or multiple layers (multi-layer) of substrates used to electrically attach electrical components and should be understood to generally include circuit cards, printed circuit cards, printed wiring cards, and printed wiring boards.

Electrical interconnection between electrically conductive paths of patterned copper in the various layers of multi-layer boards typically is accomplished through vias. The formation of the vias differs depending on the technology of the printed circuit board. Vias often are formed by drilling holes and plating the paths through the holes. The vias can extend through the complete multilayer board, and the vias and the electrical interconnections joint intersected copper patterns in each of the layers. Also the vias can extend only part way through the PCB structure and only interconnect copper in the board layers actually penetrated; such vias are called blind vias.

Current via technology is limited to using only a single direction between a first side and an opposite second side vertically along the Z axis of a board through multiple dielectric layers when drilling vias. In a PCB layout, conventional vias are parallel spaced-apart conductive through-holes extending through printed circuit board layers.

A need exists for an improved mechanism to provide enhanced electronic packaging and printed circuit board (PCB) layout that is effective and simple to implement and that does not require expensive processing and fabrication techniques.

### SUMMARY OF THE INVENTION

Principal aspects of the present invention are to provide a method and structure for implementing enhanced electronic packaging and printed circuit board (PCB) layout with diagonal vias. Other important objects of the present invention are to provide such method and structure for implementing enhanced electronic packaging and printed circuit board (PCB) layout with diagonal vias substantially without negative effect and that overcome many of the disadvantages of prior art arrangements.

In brief, a method and structure are provided for implementing enhanced electronic packaging and printed circuit board (PCB) layout. A diagonal via is formed at a selected angle between a first side and an opposite second side of a printed circuit board at a selected printed circuit board location. The diagonal via is plated with an electrically conductive material.

In accordance with features of the invention, diagonal vias are used to interconnect between a high-density pitch on the first side and a larger pitch on the opposite second side of the printed circuit board. The diagonal vias can be used to selectively interconnect electrical patterns of selected layers and eliminate the use of blind and buried vias.

### BRIEF DESCRIPTION OF THE DRAWINGS

The present invention together with the above and other objects and advantages may best be understood from the following detailed description of the preferred embodiments of the invention illustrated in the drawings, wherein:

FIG. 1 is a side view illustrating an exemplary structure including a diagonal via in accordance with the preferred embodiment;

FIG. 2 is a side view illustrating an exemplary structure including a plurality of diagonal vias in accordance with the preferred embodiment for double-sided connections to different pitch components;

FIG. 3 is a top view illustrating an exemplary structure including an array of a plurality of diagonal vias in accordance with the preferred embodiment for double-sided connections to different pitch components;

FIG. 4 is a top view illustrating a prior art escape geometry;

FIGS. 5 and 6 are top views illustrating exemplary escape geometry arrangements with diagonal vias in accordance with the preferred embodiment;

FIGS. 7A and 7B are diagrams illustrating the derivation of an effective aspect ratio of diagonal vias in accordance with the preferred embodiment;

FIG. 8 is a chart illustrating an exemplary aspect ratio as a function of via angle in accordance with the preferred embodiment.

FIG. 9 is a diagram illustrating the derivation of an effective aspect ratio of diagonal vias as a function of the pin number of ball grid array (BGA) pins in accordance with the preferred embodiment; and

FIG. 10 is a chart illustrating an exemplary aspect ratio progression for N pins of a ball grid array (BGA) in accordance with the preferred embodiment.

### DETAILED DESCRIPTION OF THE PREFERRED EMBODIMENTS

In accordance with features of the preferred embodiments, a diagonally arranged three-dimensional via or a diagonal via is provided for forming electrical connections for printed circuit boards (PCBs) and electronic packages. A laser can be used to drill holes or vias through a printed circuit board with the board tilted at a selected angle relative to the laser to form the diagonal vias. The diagonal vias are then plated with an electrically conductive material, such as copper to form electrical connections between layers. With the laser or board tilted at a variable angle, the diagonal vias formed are not perpendicular to the planar surface of the PCB. The diagonal vias enable optimization of wireability of packages in all three dimensions simultaneously.

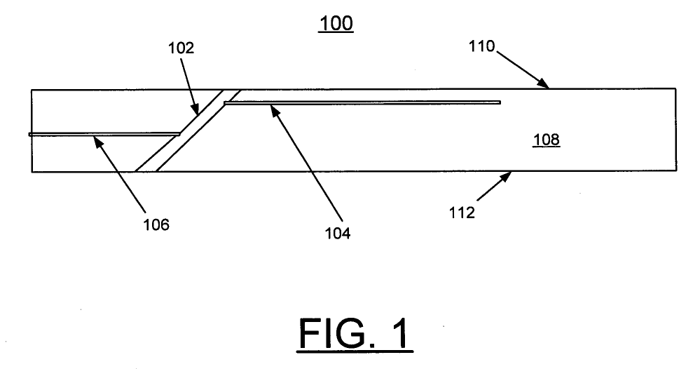

Having reference now to the drawings, in FIG. 1, there is shown an exemplary structure 100 including a diagonal via generally designated by the reference character 102 in accordance with the preferred embodiment. Structure 100 is a printed circuit board including a first signal trace 104 and a second signal trace 106 of electrical patterns on internal wiring layers within a PCB substrate 108. Diagonal vias 102 are provided for implementing enhanced electronic packaging and printed circuit board (PCB) layout.

The diagonal via 102 of the preferred embodiment can be created using a laser drill (not shown), and allowing either the card 100 or the laser to be tilted while drilling to define a variable angle of the diagonal via 102. The diagonal vias 102 of the preferred embodiment are useful for resolving many packaging challenges. The diagonal vias 102 are through vias extending between a first side 110 and an opposed second side of the PCB structure 100.

It should be understood that the diagonal vias 102 of the invention are not limited to being formed with a laser, for example, diagonal vias 102 of the invention can be created by other methods, such as 1) mechanical tooling, including standard drill techniques; 2) chemical etch techniques; and 3) generally any technique which could be used to create standard through-hole vias on PCBs.

In accordance with features of the preferred embodiments, diagonal vias 102 can be used to eliminate blind and buried vias. To implement blind and buried vias, manufacturers must perform additional drilling and lamination steps, adding cost to the final product. The diagonal vias 102 can be used in lieu of blind/buried vias. The diagonal vias 102 eliminate additional processing steps, since the diagonal vias 102 are drilled in the final step, after all the layers are already laminated together in PCB structure 100.

In accordance with features of the preferred embodiments, diagonal vias 102 advantageously are used to fan out to a larger pitch. For example, an interposer can be mounted between a fine-pitch part and the PCB 100 and diagonal vias 102 are used for driving lower cost card technology. For example, diagonal vias 102 can be used for fanning out a 1 mm pitch module to 1.27 mm pitch of the PCB 100. Such an implementation can also be applied for chip packaging, such as, modules to allow the transition between high-density modules, such as multilayer ceramic (MLC) packages to lower-density pin pitch of surface laminate carrier (SLC) packages.

In accordance with features of the preferred embodiments, diagonal vias can be used to place surface mount components on opposite sides of the package, and allow for non-compatible pin pitches while still connecting the pins between the components together correctly, for example, BGA module to a land grid array (LGA) connector. Such an implementation can reduce the wiring length of a bus, and could also allow a designer to use less PCB space. In this construct, diagonal vias allow for a single electrical construct while propagating a signal in three dimensions.

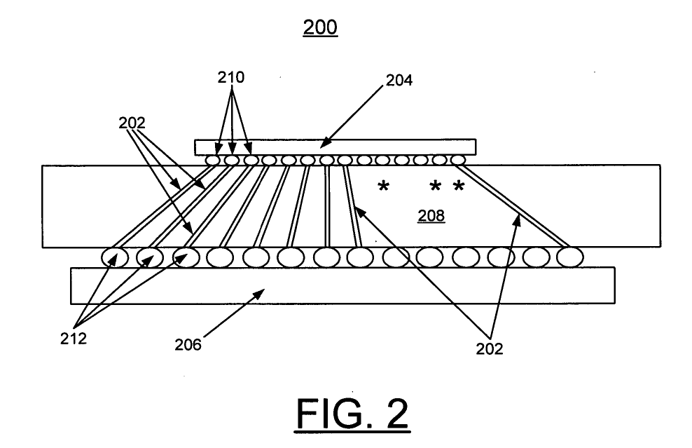

Referring now to FIG. 2, there is shown an exemplary printed circuit board structure 200 including a plurality of diagonal vias 202 in accordance with the preferred embodiment, for example, for providing double-sided connections to a pair of different pitch components 204 and 206. A plurality of openings or through holes are formed, for example, punched or laser drilled through an electrically insulative member or substrate 208 to define a respective predefined pattern on opposite first and second sides of the printed circuit board 200 and then an interior through hole sidewall is plated with a continuous layer of a metal to provide the elongated, plated diagonal vias 202 of the preferred embodiment. A plurality of pads 210 coupled to the first component 204 have a high-density pitch and are connected by the diagonal vias 202 to a plurality of pads 212 coupled to the other component 206 that has a lower density pitch.

As shown in FIG. 2 using the diagonal vias 202 for fanning out from the fine-pitch module 204 to the coarse-pitch component 204, such as another module or an LGA connector, can enable double-sided assembly in PCB areas where interconnection was previously precluded.

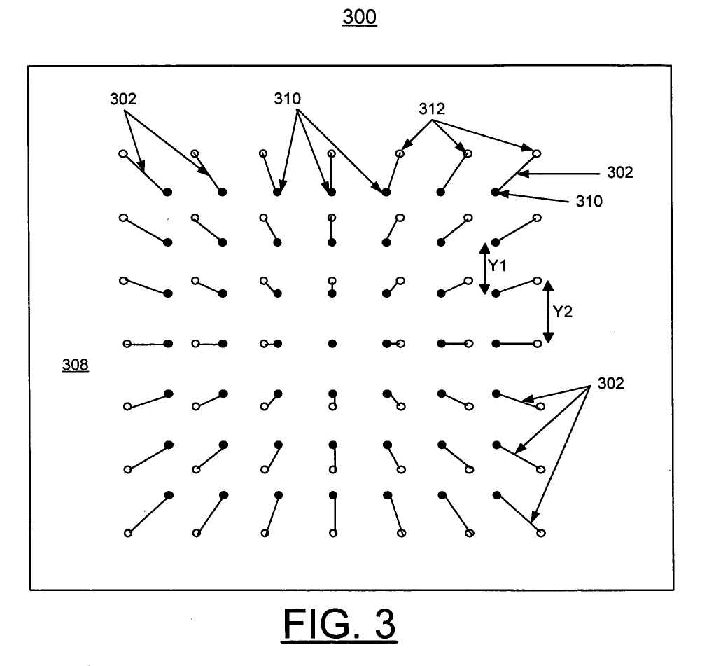

Referring also to FIG. 3, there is shown an exemplary printed circuit board structure 300 including an array of diagonal vias 302 in accordance with the preferred embodiment, for example, also for providing double-sided connections to different pitch components. The diagonal vias 302 are arranged at selected angles through a PCB substrate 308 to provide a required array pitch increase or fan-out for providing double-sided connections to different pitch components.

In FIG. 3, a plurality of first connection pads 310, each indicated by a solid circle, defines a first array on a first side of the PCB structure 300 having a high-density pitch. A plurality of pads 312, each indicated by an open circle, defines a second array on an opposed second side of the PCB structure 300 having a lower density pitch. The first connection pads 310 and the second connection pads 312 are respectively connected by the diagonal vias 302. For example, solid connection pads or pins 310 represent a 1 mm pitch module as indicated by a line labeled Y1, and the connection pads or pins 312 represent a 50-mil pitch component on the opposite side of the PCB 300 as indicated by a line labeled Y2. It should be understood that a different pitch can be provided in both the x and y directions or in one dimension.

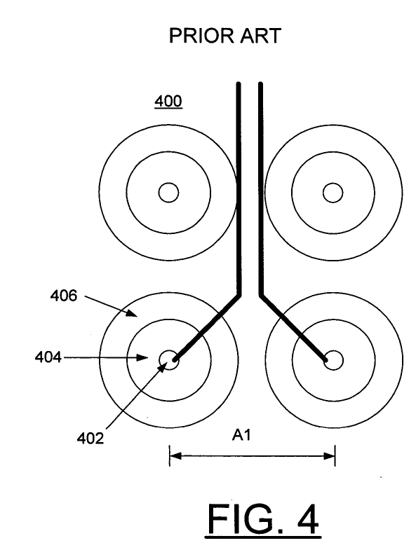

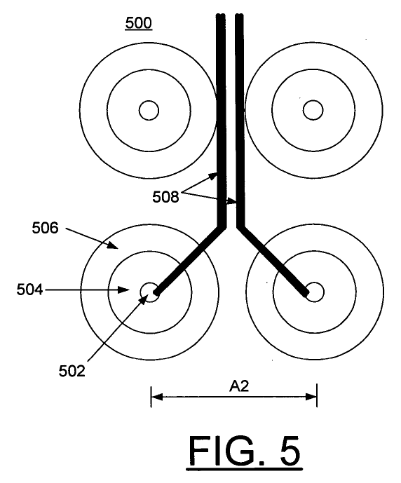

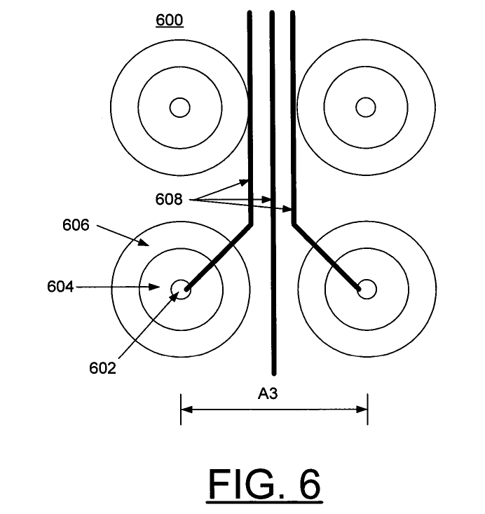

In accordance with features of the preferred embodiments, by fanning out the pins to the larger pitch, wider lines, or more escapes are allowed as respectively illustrated in FIGS. 5 and 6, as compared to standard limitations of current technology as illustrated in FIG. 4.

FIG. 4 illustrates conventional or prior art escape geometry 400 and the escape limitation of conventional card technology ground rules. A plurality of prior art 8-mil vias 402 having via spacing indicated by line labeled A1 include a 20 mil pad 404 and a 30 mil anti-pad 406. Conventional 3-mil lines with 4-mil spaces encroach proximate to the anti-pad 406 around adjacent vias 402 and no further spacing or line width is allowed.

In accordance with features of the preferred embodiments, utilizing diagonal vias of the invention, the designer can move from the tight pitch of the component to a more open pitch for escaping wires. In this way, one can avoid the use of blind or buried vias that are more expensive, and allow more wires per channel for escaping, which reduces the total number of layers required. This can result in fewer required wiring layers.

Referring also to FIGS. 5 and 6, there are shown respective exemplary escape geometry arrangements 500, 600 with respective diagonal vias 502, 602 in accordance with the preferred embodiment.

Each escape geometry arrangements 500, 600 includes a plurality of vias 502, 602 respectively having via spacing indicated by line labeled A2, A3. Each via 502, 602 includes a pad 504, 604 and an anti-pad 506, 606.

Using diagonal vias 502 as shown in FIG. 5, extra space between connections enables a pair of wider traces 508 to wire signals and thus, lower loss traces as compared to the prior art arrangement of FIG. 4. The escape geometry arrangement 500 with diagonal vias 502 allows the escaping of fine-pitch modules with lower loss, wider transmission lines that are more suited to carry high-speed signals.

Using diagonal vias 602 as shown in FIG. 6, extra space between connections enables an additional signal trace 608 or more than 2 wires per channel while escaping the module. The escape geometry arrangement 600 with diagonal vias 602 advantageously are used to fanout, for example, dense BGA pin fields, to wider pitch, to assist in gaining added wiring channels between connections or pins.

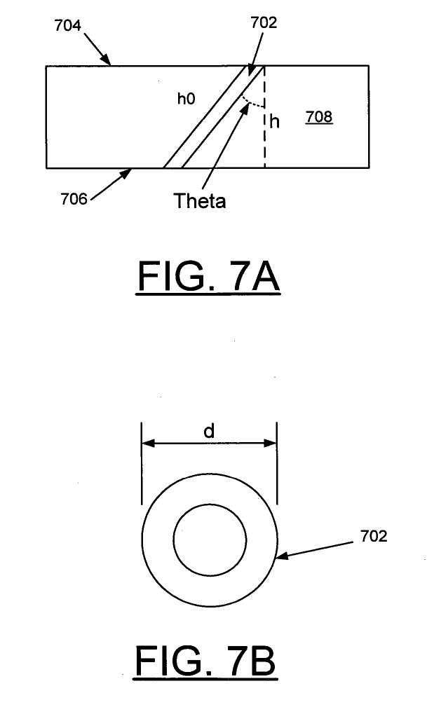

Referring now to FIGS. 7A and 7B, a variable angle of a diagonal via 702 is represented by a dotted line labeled Theta, and a thickness or height between a first side 704 and an opposite second side 706 of a printed circuit board 708 is represented by h. The diagonal via 702 has a drilled diameter represented by a line labeled d and a length indicated by h0.

A limiting factor for use of prior art vias and diagonal vias of the preferred embodiments is referred to as an aspect ratio. The aspect ratio generally is the ratio of the height of the via to its unplated diameter d. For prior art vertical through vias, this is the ratio of the thickness of the board to its drilled diameter. Aspect ratios above 13 generally result in significantly reduced raw card yield, and are undesirable. By making the via diagonal, the length of the hole is increased, thereby increasing the aspect ratio.

From FIGS. 7A and 7B, the relationship can be seen between the board thickness and an effective aspect ratio Ra of the diagonal via 702 can to be represented by:
Ra=h/d*cos(Theta)

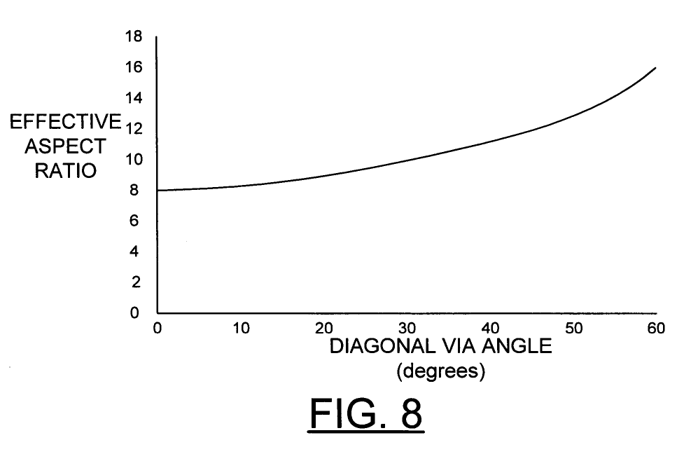

FIG. 8 shows the relationship between the via angle Theta and the effective aspect ratio for a given set of assumptions including a 80 mil board with a 10 mil drilled diameter and an 8-mil finished diameter for via 702. One can see that in this case, vias 702 could be drilled at angles up to 50 degrees before exceeding an aspect ratio of 12. Similar curves can be generated for various different values of d and h. Thicker boards will result in the requirement of smaller angles. However, the use of diagonal vias of the invention enables the reduction in the number of wiring layers, resulting in thinner boards, and further enabling larger angles for the diagonal vias.

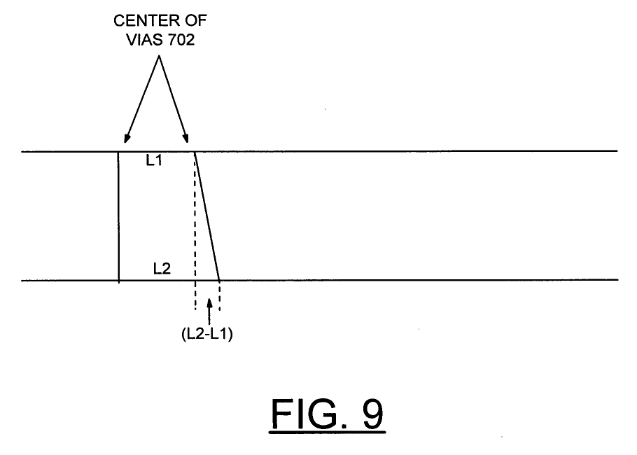

Knowing the relationships for the effective aspect ratio, the size of BGA modules can be estimated that could be fanned out to larger pitch. To determine a variable via angle as a function of the number of BGA pins, having reference to FIG. 9, L1 represents a first pitch of the smaller-pitch part, 1 mm, for instance, while L2 represents a pitch of the desired fanout, 1.27 mm, for instance.

In FIG. 9, there is shown geometry for finding aspect ratio as a function of BGA size where L1, L2 represent the spacing on opposite PCB sides between the center of vias 702. The angle of the via, as a function of the pin number, N is represented by:
Theta(N)=invtan((L1−L2)*N)/h)

Thus, by defining L1, L2, h, and the via diameter, d, we can find the aspect ratio as a function of the number of BGA pins.

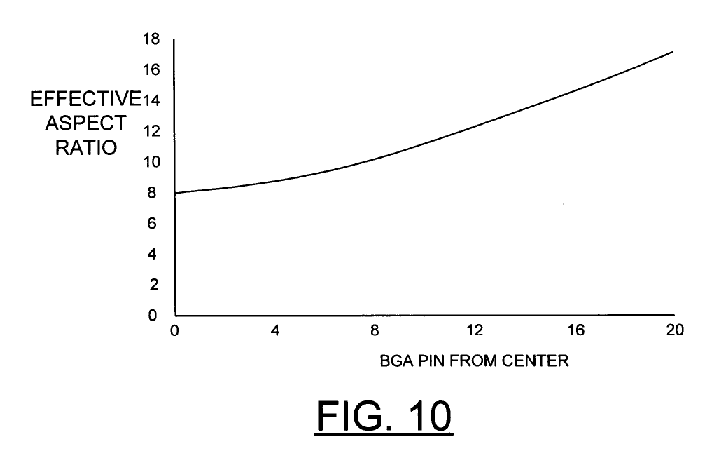

FIG. 10 shows the aspect ratio progression for N pins of a BGA, for the invention as implemented in FIG. 6, for increased wireability. The same assumptions apply for this calculation as for those in FIG. 8, 80 mil PCB thickness, 10 mil=d, the initial diameter of the via before being plated, 1 mm fanned out to 1.18 mm.

In FIG. 10, as shown the aspect ratio approaches 12 for the 12th pin from the center. Using this invention, BGA wireability can be improved on certain layers, for these assumptions, up to 33% for modules as large as 24×24. Similar curves can be generated for other values of L1, L2, d, and h.

While the present invention has been described with reference to the details of the embodiments of the invention shown in the drawing, these details are not intended to limit the scope of the invention as claimed in the appended claims.

1. A method for implementing enhanced electronic packaging and printed circuit board layout comprising the steps of:
forming a diagonal via at a selected angle between a first side and an opposite second side of a printed circuit board at a selected printed circuit board location; and
plating said diagonal via with an electrically conductive material.

2. A method as recited in claim 1 wherein the step of forming a diagonal via includes the steps of using a laser for drilling said diagonal via with the printed circuit board tilted relative the laser.

3. A method as recited in claim 1 includes the steps of forming a plurality of said diagonal vias to provide a respective predefined connection pattern on each of said first side and said opposite second side of the printed circuit board.

4. A method as recited in claim 3 wherein said respective predefined connection pattern on each of said first side and said opposite second side of the printed circuit board enabling interconnection of different pin pitches.

5. A method as recited in claim 3 wherein said plurality of said diagonal vias provide a first predefined connection pattern on said first side of the printed circuit board for a first array pitch and a second predefined connection pattern on said opposite second side of the printed circuit board for a second array pitch.

6. A method as recited in claim 5 wherein said first side of the printed circuit board includes a predefined high-density pitch and wherein said second array pitch is larger than said first array pitch for selectively providing a wider pitch surface area for interconnect wiring patterns of the printed circuit board.

7. A method as recited in claim 5 wherein said second array pitch is larger than said first array pitch and said second predefined connection pattern enables selectively adding wiring channels between said diagonal vias or defining wider signal traces between said diagonal vias.

8. A method as recited in claim 1 wherein the step of forming said diagonal via includes the steps of forming said diagonal via for interconnecting electrical patterns of selected layers of the printed circuit board and eliminate the use of blind and buried vias.

9. A structure for implementing enhanced electronic packaging and printed circuit board layout comprising:
a diagonal via formed at a selected angle between a first side and an opposite second side of a printed circuit board at a selected printed circuit board location; and
said diagonal via being plated with an electrically conductive material.

10. A structure as recited in claim 9 wherein a plurality of said diagonal vias define a respective predefined connection pattern on each of said first side and said opposite second side of the printed circuit board.

11. A structure as recited in claim 10 wherein said predefined connection pattern on said opposite second side of the printed circuit board provides a predefined larger array pitch than said predefined connection pattern on said first side of the printed circuit board.

12. A structure as recited in claim 11 wherein said first side of the printed circuit board includes a predefined first high-density array pitch and wherein said second array pitch is larger than said first array pitch for providing a wider pitch surface area for interconnection of multiple wiring patterns of the printed circuit board.

13. A structure as recited in claim 11 wherein said predefined array pitch of said second predefined connection pattern enables selectively adding wiring channels between said diagonal vias or defining wider signal traces between said diagonal vias.

14. A structure as recited in claim 11 wherein said diagonal via selectively interconnects electrical patterns of selected layers of the printed circuit board and eliminate the use of blind and buried vias.

15. A printed circuit board structure comprising:
a substrate used to electrically attach electrical components; said substrate having first side and an opposite second side;
a diagonal via formed at a selected location; said diagonal via having a selected angle between said first side and said opposite second side; and
said diagonal via being plated with an electrically conductive material.

16. A printed circuit board structure as recited in claim 15 wherein a plurality of said diagonal vias define a respective predefined connection pattern on each of said first side and said opposite second side.

17. A printed circuit board structure as recited in claim 16 wherein said respective predefined connection pattern on each of said first side and said opposite second side enable interconnection of a high-density module to a lower density module.

18. A printed circuit board structure as recited in claim 16 wherein said respective predefined connection pattern on each of said first side and said opposite second side includes a predefined array pitch and wherein said second array pitch is larger than said first array pitch for providing a wider pitch surface area for interconnection of multiple wiring patterns of the printed circuit board.

19. A printed circuit board structure as recited in claim 15 includes multiple substrate layers having electrical patterns and wherein said diagonal via selectively interconnects electrical patterns of selected layers and eliminate the use of blind and buried vias.
